(19) United States
(12) Patent Application Publication
(10) Pub. No.: US 2014/0299189 A1
(43) Pub. Date: Oct. 9, 2014

(54) SOLAR CELL

(71) Applicant: Electronics and Telecommunications Research Institute, Daejeon (KR)

(72) Inventors: JungWook LIM, Daejeon (KR); Sun Jin YUN, Daejeon (KR); Da Jung LEE, Daejeon (KR)

(73) Assignee: Electronics and Telecommunications Research Institute, Daejeon (KR)

(21) Appl. No.: 14/218,176

(22) Filed: Mar. 18, 2014

(30) Foreign Application Priority Data
Apr. 4, 2013 (KR) 10-2013-0036892
Oct. 25, 2013 (KR) 10-2013-0127993

(51) Int. Cl. H01L 31/0745

(52) U.S. Cl. CPC H01L 31/0745
USPC 136/261; 136/252

(57) ABSTRACT

Provided is the structure of a thin film solar cell. The structure of the thin film solar cell includes a first substrate, a first electrode provided on the first substrate, a p-type semiconductor layer provided on the first electrode, a first buffer layer provided on the p-type semiconductor layer, an optical absorption region provided on the first buffer layer, a second buffer layer provided on the optical absorption region, an n-type semiconductor layer provided on the second buffer layer, a second electrode provided on the n-type semiconductor layer, and a second substrate on the second electrode. The optical absorption region includes a silicon layer, a first layer on the silicon layer, and a second layer having a different energy band gap from the first layer, on the first layer.

### CROSS-REFERENCE TO RELATED APPLICATIONS

This U.S. non-provisional patent application claims priority under 35 U.S.C. §119 of Korean Patent Application Nos. 10-2013-0036892, filed on Apr. 4, 2013, and 10-2013-0127993, filed on Oct. 25, 2013, the entire contents of which are hereby incorporated by reference.

### BACKGROUND OF THE INVENTION

The present disclosure herein relates to a solar cell, and more particularly, to a thin film solar cell.

At present, in the solar cell market mainly formed with crystalline silicon as the center, a thin film solar cell is expected to expand its importance for the application of solar cells in diverse types. Solar cells studied most actively include dye-sensitized solar cells. The dye-sensitized solar cells have advantages of high transmittance, the realization of diverse colors, and the like, however have defects concerning stability, life and deterioration of efficiency in a large area. Therefore, a transparent solar cell having improved efficiency and transmittance at the same time, consuming less cost and maintaining thin film properties is necessary.

### SUMMARY OF THE INVENTION

The present disclosure provides the structure of a thin film solar cell maintaining high transmittance and high efficiency.

The structure of a thin film solar cell for solving the above-described technical task is suggested.

Embodiments of the inventive concept provide thin film solar cells including a first substrate, a first electrode provided on the first substrate, a p-type semiconductor layer provided on the first electrode, a first buffer layer provided on the p-type semiconductor layer, an optical absorption region provided on the first buffer layer, a second buffer layer provided on the optical absorption region, an n-type semiconductor layer provided on the second buffer layer, a second electrode provided on the n-type semiconductor layer, and a second substrate on the second electrode. The optical absorption region includes a silicon layer, a first layer on the silicon layer, and a second layer having a different energy band gap from the first layer, on the first layer.

In some embodiments, the first layer may be a first silicon germanium layer, and the second layer may be a silicon layer.

In other embodiments, the thin film solar cell may further include a second silicon germanium layer having a different band gap from the first silicon germanium layer, between the first layer and the second layer.

In still other embodiments, the thin film solar cell may further include a second silicon germanium layer having a different band gap from the first silicon germanium layer, on the second layer.

In even other embodiments, the first layer may be a first silicon germanium layer, and the second layer may be a second silicon germanium layer having a different band gap from the first silicon germanium layer. In addition, a third silicon germanium layer having a different band gap from the first and second silicon germanium layers may be further included on the second layer.

In yet other embodiments, each of the first buffer layer and the second buffer layer may include a plurality of silicon layers having different band gaps from each other.

In further embodiments, the band gaps of the plurality of silicon layers in the first buffer layer may increase in a direction toward the p-type semiconductor layer.

In still further embodiments, a thickness of the p-type semiconductor layer may be from about 2 nm to about 15 nm.

In other embodiments of the inventive concept, thin film solar cells include a first substrate, a first electrode provided on the first substrate, a p-type semiconductor layer provided on the first electrode, a first buffer layer provided on the p-type semiconductor layer, an optical absorption region provided on the first buffer layer, a second buffer layer provided on the optical absorption region, an n-type semiconductor layer provided on the second buffer layer, a second electrode provided on the n-type semiconductor layer, and a second substrate on the second electrode. Each of the first buffer layer and the second buffer layer includes a plurality of silicon layers having different band gaps from each other.

In some embodiments, the band gaps of the plurality of silicon layers in the first buffer layer may increase in a direction toward the p-type semiconductor layer.

In other embodiments, a thickness of each of the first buffer layer and the second buffer layer may be from about 5 nm to about 30 nm.

In still other embodiments, a band gap of the first buffer layer may be from about 1.7 eV to about 2.0 eV.

In still other embodiments of the inventive concept, thin film solar cells include a first substrate, a first electrode provided on the first substrate, a p-type semiconductor layer provided on the first electrode, a first buffer layer provided on the p-type semiconductor layer, an optical absorption region provided on the first buffer layer, a second buffer layer provided on the optical absorption region, an n-type semiconductor layer provided on the second buffer layer, a second electrode provided on the n-type semiconductor layer, and a second substrate on the second electrode. A thickness of the p-type semiconductor layer is from about 2 nm to about 15 nm.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view illustrating the structure of a thin film solar cell according to an embodiment of the inventive concept;

FIGS. 2 to 5 are cross-sectional views illustrating the structures of thin film solar cells including a multi layer of silicon and silicon germanium according to embodiments of the inventive concept;

FIG. 6A is a cross-sectional view illustrating the structure of a thin film solar cell according to another embodiment of the inventive concept;

FIG. 6B is an enlarged view of part A of FIG. 6A;

FIG. 6C is an enlarged view of part B of FIG. 6A; and

FIG. 7 is a graph illustrating the quantum efficiency of thin film solar cells according to embodiments of the inventive concept with respect to wavelengths.

### DETAILED DESCRIPTION OF PREFERRED EMBODIMENTS

Hereinafter example embodiments will be described in detail with reference to the accompanying drawings illustrating the structures of the thin film solar cells according to the inventive concept.

Example embodiments of the inventive concept will be described below in more detail with respect to conventional techniques for sufficient understanding of the advantage and the effect of the inventive concept with reference to the accompanying drawings. Particularly, the inventive concept may be attentively pointed out and clearly claimed in attached claims. The inventive concept may, however, be embodied in different forms and should not be construed as limited to the embodiments set forth herein. Rather, these embodiments are provided so that this description will be thorough and complete. Like reference numerals refer to like elements throughout.

Hereinafter the structure of the thin film solar cell according to an embodiment of the inventive step will be described in detail with reference to the accompanying drawings.

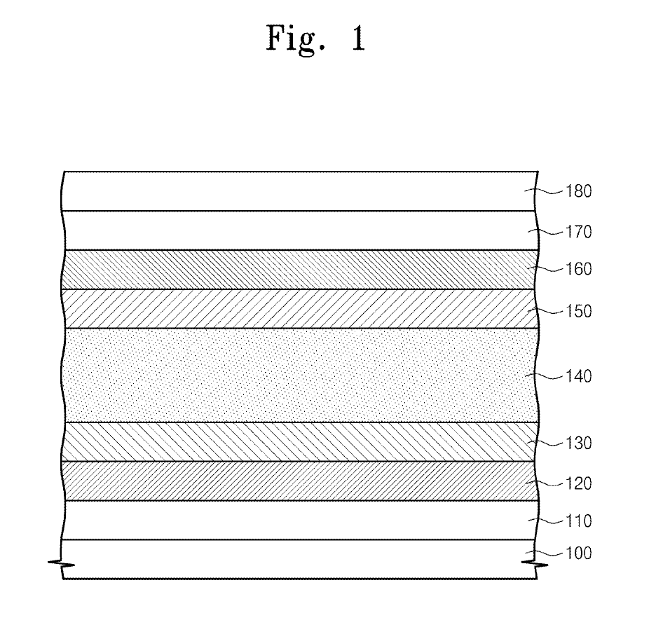

FIG. 1 is a cross-sectional view illustrating the structure of a thin film solar cell according to an embodiment of the inventive concept.

Referring to FIG. 1, a thin film solar cell may include a first substrate 100, a first electrode 110, a p-type semiconductor layer 120, a first buffer layer 130, an optical absorption region 140, a second buffer layer 150, an n-type semiconductor layer 160, a second electrode 170 and a second substrate 180.

The first substrate 100 may provide spaces for disposing functional layers. The first substrate 100 may be formed by using a transparent and non-conductive material so that incident light may effectively reach a photoelectric transducer. For example, the first substrate 100 may be glass or plastic. More particularly, the first substrate 100 may include polymethylmethacrylate (PMMA), acrylonitrile styrene (AS), polystyrene (PS), polycarbonate (PC), polyethersulfone (PES), polyamide (PA), polyesterimide (PEI) or polymethylpentene (PMP).

On the first substrate 100, the first electrode 110 may be formed. The first electrode 110 may be formed by using a light transmitting and conductive material to increase the transmittance of incident light. For example, the first electrode 110 may be a transparent conductive oxide (TCO). The TCO may include a tin oxide-based material or a zinc oxide-based material. On the top surface of the first electrode 110, a plurality of embossing having a random pyramidal structure may be formed. In other words, the first electrode 110 may have a texturing surface (not illustrated). The texturing surface may lower the reflection of incident light and increase light absorptivity, thereby improving the efficiency of the solar cell.

On the first electrode 110, the p-type semiconductor layer 120 may be formed. The p-type semiconductor layer 120 may be formed by doping boron and carbon into amorphous silicon (a-Si). The p-type semiconductor layer 120 may have the band gap of greater than or equal to about 1.9 eV for smooth penetration of incident light. The thickness of the p-type semiconductor layer 120 may be generally from about 5 nm to about 30 nm. When the thickness of the p-type semiconductor layer 120 is small, an open circuit voltage and a curve factor may be markedly decreased, and a short circuit current may be increased. The open circuit voltage may increase by the structure of a plurality of the first buffer layers 130, that will be described herein below. Therefore, when the thickness of the p-type semiconductor layer 120 decreases, the transmittance may be increased and the short circuit current may be increased. The thickness of the p-type semiconductor layer 120 may be from about 2 nm to about 15 nm.

On the p-type semiconductor layer 120, the first buffer layer 130 may be formed. The first buffer layer 130 may be formed as a single layer or a multi layer. The first buffer layer 130 may include any one among silicon, silicon carbide and silicon oxide. When the first buffer layer 130 is silicon, an energy band gap may be controlled by changing the dilution ratio of hydrogen. The band gap of the first buffer layer 130 may be increased when using silicon having a small dilution ratio of hydrogen, which may be deposited in the conditions of high concentration of silane. The buffer layer 130 may have the energy band gap of from about 1.7 eV to about 2.0 eV. The band gap of the first buffer layer 130 may be greater than the band gap of the p-type semiconductor layer 120. The thickness of the first buffer layer 130 may be from about 5 nm to about 30 nm. The first buffer layer 130 may prevent the recombination of electrons and holes generated at the interface of the p-type semiconductor layer 120 and the optical absorption region 140, and may increase the efficiency of the thin film solar cell.

On the first buffer layer 130, the optical absorption region 140 may be formed. The optical absorption region 140 may be formed as a single layer of silicon germanium, or a multi layer of silicon and silicon germanium. As the amount of the silicon germanium increases, the energy band gap of the optical absorption region 140 may decrease and may be from about 1.3 eV to about 1.6 eV. The optical absorption region 140 formed by using the silicon germanium has higher light absorptivity than silicon, and the optical absorption region 140 may be formed thinly. The thickness of the optical absorption region 140 may be from about 90 nm to about 180 nm.

On the optical absorption region 140, the second buffer layer 150 may be formed. The second buffer layer may be formed as a single layer or a multi layer. The second buffer layer 150 may include silicon or silicon germanium. As the amount of the silicon germanium increases, the energy band gap of the second buffer layer may decrease. When the second buffer layer 150 includes the silicon germanium, the energy band gap of the second buffer layer 150 may be lower than the first buffer layer 130. The thickness of the second buffer layer 150 may be from about 5 nm to about 30 nm.

On the second buffer layer 150, the n-type semiconductor layer 160 may be formed. The n-type semiconductor layer may be formed by doping phosphor and carbon into a-Si.

On the n-type semiconductor layer 160, the second electrode 170 may be formed. The second electrode 170 may be formed by using a light transmitting and conductive material to increase the transmittance of incident light. For example, the second electrode 170 may be a TCO. The TCO may include a tin oxide-based material or a zinc oxide-based material. On the bottom surface of the second electrode 170, a plurality of embossing having a random pyramidal structure may be formed. In other words, the second electrode 170 may have a texturing surface (not illustrated). The texturing surface may lower the reflection of incident light and increase light absorptivity, thereby improving the efficiency of the solar cell.

On the second electrode 170, the second substrate 180 may be provided. The second substrate 180 may provide spaces for disposing other functional layers. The second substrate 180 may be a transparent and non-conductive material so that incident light may effectively reach a photoelectric transducer. For example, the second substrate 180 may be glass or plastic. More particularly, the second substrate 180 may include PMMA, AS, PS, PC, PES, PA, PEI or PMP.

Meanwhile, exemplary embodiments on the structure of the solar cell according to the inventive concept are explained with a p-i-n structure, however the structure is not limited thereto, and an n-i-p structure from the incident surface of light may be possible.

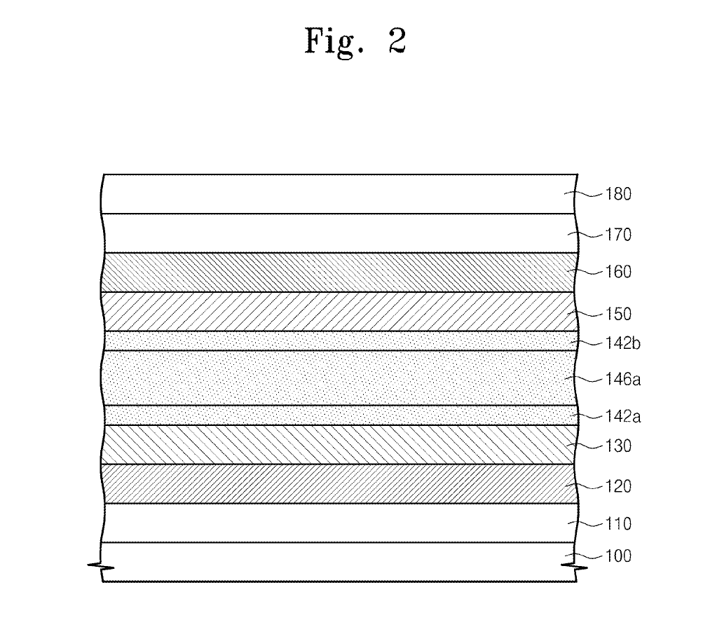

FIGS. 2 to 5 are cross-sectional views illustrating the structures of thin film solar cells including a multi layer of silicon and silicon germanium according to embodiments of the inventive concept.

Referring to FIG. 2, an optical absorption region 140 may include a first silicon layer 142a, a first silicon germanium layer 146a on the first silicon layer 142a and a second silicon layer 142b having a different band gap from the first silicon layer 142a, on the first silicon germanium layer 146a.

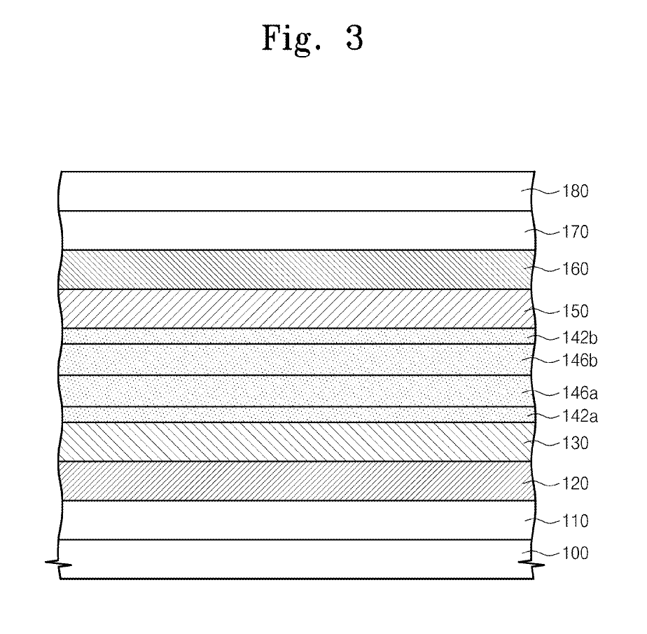

Referring to FIG. 3, an optical absorption region 140 may include a second silicon germanium layer 146b having a different band gap from the first silicon germanium layer 146a, between the first silicon germanium layer 146a and the second silicon layer 142b of FIG. 2. Since the energy band gaps of the first silicon germanium layer 146a and the second silicon germanium layer 146b are different from each other, quantum efficiency and transmittance may be increased.

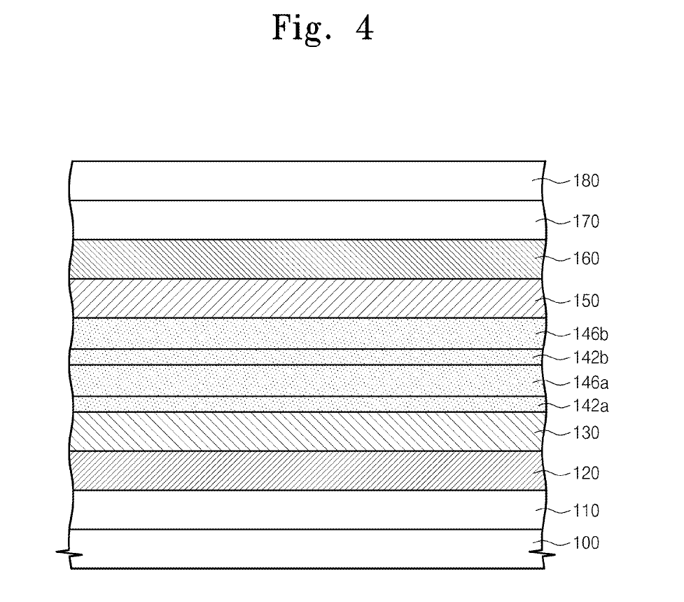

Referring to FIG. 4, an optical absorption region 140 may include a second silicon germanium layer 146 having a different band gap from the first silicon germanium layer 146a, on the second silicon layer 142b of FIG. 2.

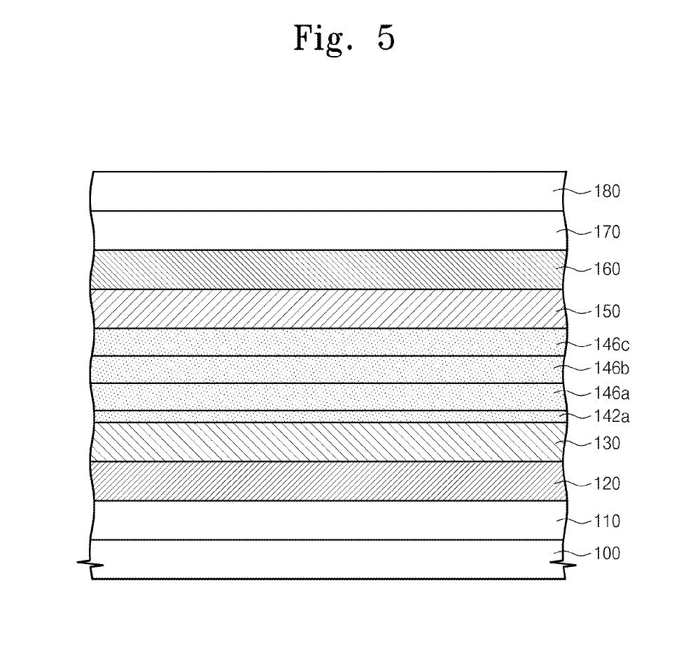

Referring to FIG. 5, an optical absorption region 140 may include a first silicon layer 142a, a first silicon germanium layer 146a on the first silicon layer 142a, a second silicon germanium layer 146b having a different band gap from the first silicon germanium layer 146a, on the first silicon germanium layer 146a, and a third silicon germanium layer 146c having a different band gap from the first and second silicon germanium layers 146a and 146b, on the second silicon germanium layer 146b.

The inner structures of the optical absorption regions 140 of FIGS. 2 to 5 are not limited to the above-described structures, however diverse combinations of a plurality of silicon layers and silicon germanium layers having different band gaps may be included.

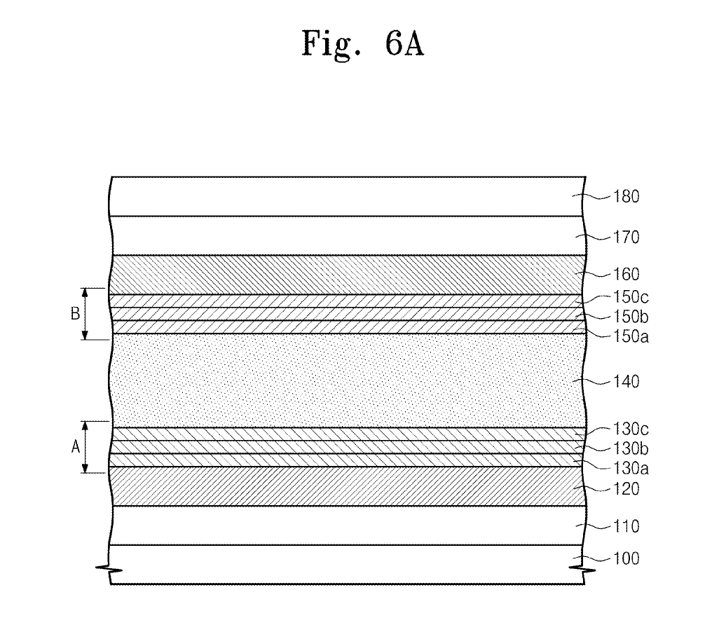

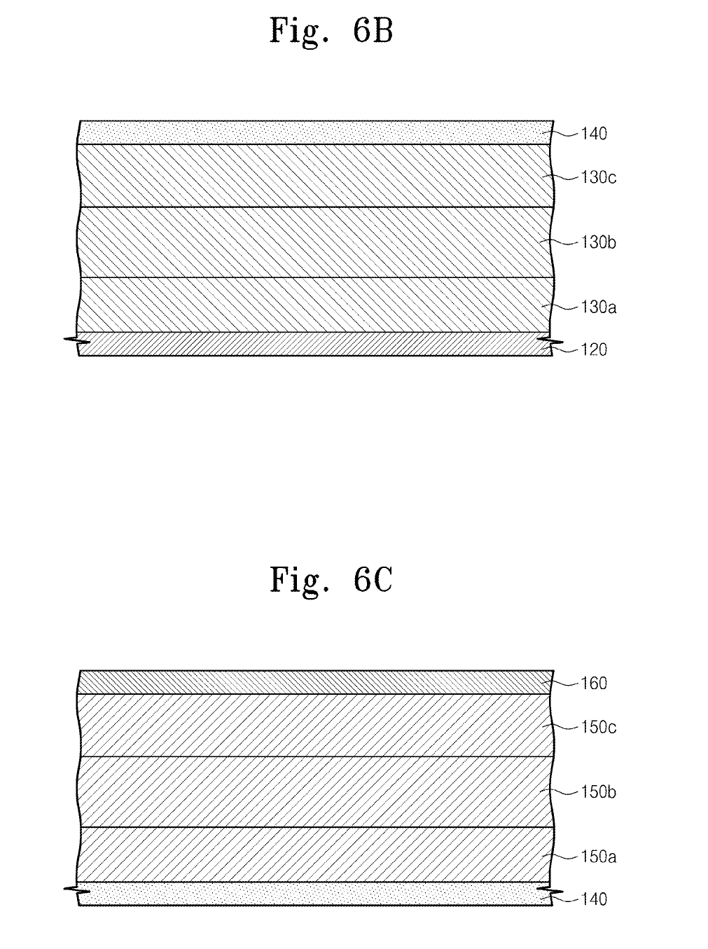

FIG. 6A is a cross-sectional view illustrating the structure of a thin film solar cell according to another embodiment of the inventive concept. FIG. 6B is an enlarged view of part A of FIG. 6A. FIG. 6C is an enlarged view of part B of FIG. 6A.

Referring to FIGS. 6A to 6C, a first buffer layer 130 may include three silicon layers 130a, 130b and 130c having different band gaps from each other. A second buffer layer 150 may include three silicon layers 150a, 150b and 150c having different band gaps from each other. When the first buffer layer 130 and the second buffer layer 150 are silicon, the band gap may be changed by changing the dilution ratio of hydrogen as described above. The band gap of the silicon layers 130a, 130b and 130c in the first buffer layer 130 may increase in a direction toward a p-type semiconductor layer 120. In other words, the band gap of the first silicon layer 130a may be greater than the second silicon layer 130b and the third silicon layer 130c, and the band gap of the second silicon layer 130b may be greater than the third silicon layer 130c. The thicknesses of the silicon layers 130a, 130b, 130c, 150a, 150b and 150c of the first and second buffer layers 130 and 150 may be different from each other. The number of the silicon layers included in each of the first buffer layer 130 and the second buffer layer 150 is not limited to the number illustrated in the drawings.

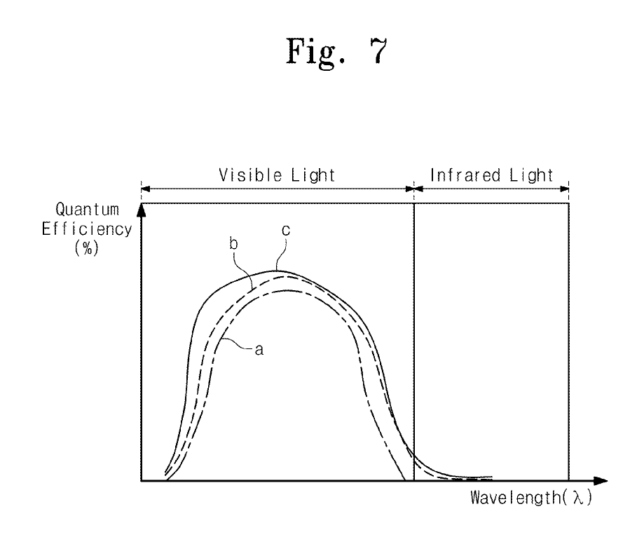

FIG. 7 is a graph illustrating the quantum efficiency of thin film solar cells according to embodiments of the inventive concept with respect to wavelengths.

Referring to FIG. 7, graph “a” corresponds to the quantum efficiency of a common silicon thin film solar cell with respect to wavelengths. Graph “b” corresponds to the quantum efficiency of a thin film solar cell including the first and second buffer layers 130 and 150, and the optical absorption region 140 according to the inventive concept with respect to wavelengths. In graph “b”, the thickness of the optical absorption region 140 is about 150 nm, the thickness of each of the silicon layers 130a, 130b and 130c in the first buffer layer 130 is about 5 nm, and the band gaps thereof are about 1.8 eV, about 1.75 eV and about 1.7 eV, respectively. The thickness of each of the silicon layers 150a, 150b and 150c in the second buffer layer 150 is about 7 nm, and the band gaps thereof are about 1.8 eV, about 1.75 eV and about 1.7 eV, respectively.

In addition, graph “c” illustrates the quantum efficiency of a thin film solar cell including a p-type semiconductor layer 120 having a decreased thickness with respect to wavelengths. The quantum efficiency of graph “c” is improved over the whole wavelength regions when compared to graphs “a” and “b”. In addition, the absorptivity of long wavelength in an infrared region is improved for of graph “c” when compared to graphs “a” and “b” because of a low energy band gap. The quantum efficiency of graph “c” is increased over the whole wavelength region when compared to graph “b”.

The structure of a thin film solar cell according to an embodiment of the inventive concept includes a plurality of optical absorption regions, a plurality of first buffer layers, a plurality of second buffer layers and/or a thin p-type semiconductor layer. Thus, a thin film solar cell having high transmittance and high efficiency at the same time may be realized.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thin film solar cell, comprising:
a first substrate;
a first electrode provided on the first substrate;
a p-type semiconductor layer provided on the first electrode;
a first buffer layer provided on the p-type semiconductor layer;
an optical absorption region provided on the first buffer layer;
a second buffer layer provided on the optical absorption region;
an n-type semiconductor layer provided on the second buffer layer;
a second electrode provided on the n-type semiconductor layer; and
a second substrate on the second electrode,
the optical absorption region including a silicon layer, a first layer on the silicon layer, and a second layer having a different energy band gap from the first layer, on the first layer.

2. The thin film solar cell of claim 1, wherein the first layer is a first silicon germanium layer, and the second layer is a silicon layer.

3. The thin film solar cell of claim 2, further comprising a second silicon germanium layer having a different band gap from the first silicon germanium layer, between the first layer and the second layer.

4. The thin film solar cell of claim 2, further comprising a second silicon germanium layer having a different band gap from the first silicon germanium layer, on the second layer.

5. The thin film solar cell of claim 1, wherein the first layer is a first silicon germanium layer, and the second layer is a second silicon germanium layer having a different band gap from the first silicon germanium layer, and
a third silicon germanium layer having a different band gap from the first and second silicon germanium layers is further comprised on the second layer.

6. The thin film solar cell of claim 1, wherein each of the first buffer layer and the second buffer layer includes a plurality of silicon layers having different band gaps from each other.

7. The thin film solar cell of claim 6, wherein the band gaps of the plurality of silicon layers in the first buffer layer increase in a direction toward the p-type semiconductor layer.

8. The thin film solar cell of claim 1, wherein a thickness of the p-type semiconductor layer is from about 2 nm to about 15 nm.

9. A thin film solar cell, comprising:
a first substrate;
a first electrode provided on the first substrate;
a p-type semiconductor layer provided on the first electrode;
a first buffer layer provided on the p-type semiconductor layer;
an optical absorption region provided on the first buffer layer;
a second buffer layer provided on the optical absorption region;
an n-type semiconductor layer provided on the second buffer layer;
a second electrode provided on the n-type semiconductor layer; and
a second substrate on the second electrode,
each of the first buffer layer and the second buffer layer including a plurality of silicon layers having different band gaps from each other.

10. The thin film solar cell of claim 9, wherein the band gaps of the plurality of silicon layers in the first buffer layer increase in a direction toward the p-type semiconductor layer.

11. A thin film solar cell, comprising:
a first substrate;
a first electrode provided on the first substrate;
a p-type semiconductor layer provided on the first electrode;
a first buffer layer provided on the p-type semiconductor layer;
an optical absorption region provided on the first buffer layer;
a second buffer layer provided on the optical absorption region;
an n-type semiconductor layer provided on the second buffer layer;
a second electrode provided on the n-type semiconductor layer; and
a second substrate on the second electrode,
a thickness of the p-type semiconductor layer being from about 2 nm to about 15 nm.
